(19) United States
(12) Patent Application Publication
(10) Pub. No.: US 2007/0242430 A1
(43) Pub. Date: Oct. 18, 2007

(54) FAN FRAME DEVICE

(76) Inventors: WEN-HAO LIU, Taipei (TW); Shou-Te Yu, Taipei (TW); Bor-Haw Chang, Taipei (TW)

Correspondence Address: G. LINK CO., LTD., 3550 BELL ROAD, MINOOKA, IL, 60447, US

(21) Appl. No.: 11/279,893

(22) Filed: Apr. 15, 2006

(51) Int. Cl. H05K 7/20; F28F 7/00

(52) U.S. Cl. 361/695; 165/125; 165/80.3; 165/252

(57) ABSTRACT

A fan frame device includes a plastic frame member and a metal reinforcing member. The inner side of the frame defines a flow path for receiving a fan wheel. The metal reinforcing member is joined to the frame member integrally. The inner side of the frame is arranged to have a largest diameter so that the flow passage provides more space for accommodating a larger sized fan wheel. Hence, strength of the frame is reinforced, vibration and noise are reduced during a fan wheel running and integral effect of heat dissipation is enhanced largely.

### BACKGROUND OF THE INVENTION

1. Field of the Invention

The present invention is related to a fan frame device and particularly to a fan frame, which provides a plastic frame member and a metal reinforcing member.

2. Brief Description of the Related Art

The fan is an essential part of air-cooling radiator device and plays an important role for heat dissipation effect. The fan is the only movable part in the radiator device. Meanwhile, noise of the radiator device is influenced directly by the fan. The fan induces air to move through the cooling fins with a specific speed and a specific way for heat exchange being performed between the air and the cooling fins such that accumulated heat at the cooling fins can be carried away to achieve heat removal with forced convection.

Air flow and air pressure are factors deciding how powerful a fan is. The air flow refers a product of an area of the air passing through and a velocity of the air passing through the area. When the velocity is constant, larger outer diameter of the fan wheel leads to larger flowing area and more air flow can be induced. More air flow allows the cool air absorbs more heat so that the moving air can carry with more heat and effect of heat dissipation is enhanced. The air pressure refers addition of a static pressure and a dynamic pressure of the air so that greater air pressure enhances air-delivering capability of the fan.

In order to promote the gross effect of heat dissipation, the big sized fan has been employed to enhance heat dissipation efficiency. However, due to space limitation, not all the cooling systems are able to use the big sizes fan even if the smaller sized fan is unable to reach the expect effect of heat dissipation.

The inventor has found that if the inner side of the fan frame, i.e., the flow path of air, is increased radially under a condition of the size of the fan frame being unchanged, that is, the material between the outer side and the inner side becomes thinner. In other words, the air inlet and the air outlet areas can be increased and a bigger size fan wheel can be mounted to the inner side for generating more air flow.

Further, the inventor has found that most part of a fan frame is made of plastics and a little part of the fan frame is made of metal. The fan frame with plastic material is light but the strength thereof becomes weak in case of the fan frame being made thinner. The plastic fan frame is easy to become deformed in case of being subjected to a fore and to become soft in case of being subjected to a high ambient temperature for a long period of time. As a result, normal operation of the fan is affected substantially.

The metal fan frame provides enough strength but it is heavy and easy to produce louder noise while the air passing the fan frame to hit the inner wall of the fan frame. In addition, the metal fan frame is more costly than the plastic fan frame and manufacturing process of the metal fan frame is more complicated than the plastic fan frame.

### SUMMARY OF THE INVENTION

In order to solve the preceding problems, an object of the present invention is to provide a fan frame device with which the inner side of the fan frame member expands toward the outer side thereof to the most for the flow path thereof being able to accommodate a fan wheel with a bigger diameter and promoting heat dissipation effect.

Another object of the present invention is to provide a fan frame structure in which the fan frame is composed of a plastic frame member and a metal reinforcing member for strengthening the fan frame and lessening noise and vibration.

Accordingly, the fan frame device according to the present invention includes a plastic frame member and a metal reinforcing member. The frame member has an outer side and an inner side. The inner side of the frame member defines a flow path for accommodating a fan wheel. The metal reinforcing member is joined to the frame integrally. The inner side of the frame is arranged to have a largest diameter so that the flow path provides more space for accommodating a larger size fan wheel. Hence, strength of the frame is reinforced, vibration and noise are reduced during a fan wheel running and integral effect of heat dissipation is enhanced largely.

### BRIEF DESCRIPTION OF THE DRAWINGS

The detail structure, the applied principle, the function and the effectiveness of the present invention can be more fully understood with reference to the following description and accompanying drawings, in which:

FIG. 1 is a perspective view of the first embodiment of a fan frame device according to the present invention;

FIG. 2 is a fragmentary sectional view along line A-A of FIG. 1;

FIG. 3 is a perspective view illustrating a metal reinforcing member being disposed between the inner side and the outer side of the first embodiment of a fan frame according to the present invention;

FIG. 4 is a perspective view of the metal reinforcing member being disposed at the outer side of the first embodiment of a fan frame device according to the present invention;

FIG. 5 is a plan view of the first embodiment of a fan frame device according to the present invention illustrating the first type discontinuously shaped metal reinforcing member;

FIG. 5A is an enlarged view of the dashed circle area of FIG. 5;

FIG. 6 is another plan view of the first embodiment of a fan frame device according to the present invention illustrating the second type discontinuously shaped metal reinforcing member;

FIG. 7 is a further plan view of the first embodiment of a fan frame device according to the present invention illustrating the third type discontinuously shaped metal reinforcing member;

FIG. 7A is an enlarged view of the dashed circle area of FIG. 5;

FIG. 8 is a perspective view illustrating the fourth type discontinuously shaped metal reinforcing member of the first embodiment of a fan frame device according to the present invention;

FIG. 9 is a perspective view illustrating two fan wheels being mounted in series to the first embodiment of a fan frame device according to the present invention;

FIG. 10 is a perspective view illustrating the first type arrangement of the second embodiment of a fan frame device according to the present invention;

FIG. 11 is a perspective view illustrating the second type arrangement of the second embodiment of a fan frame device according to the present invention;

FIG. 12 is a perspective view illustrating the third type arrangement of the second embodiment of a fan frame device according to the present invention;

FIG. 13 is a perspective view illustrating the metal reinforcing member in the first type arrangement of the second embodiment of a fan frame device according to the present invention shown in FIG. 10 providing ventilating apertures;

FIG. 14 is a perspective view illustrating the second type arrangement of the second embodiment of a fan frame device according to the present invention shown in FIG. 11 providing air apertures;

FIG. 15 is a perspective view illustrating the third type arrangement of the second embodiment of a fan frame device according to the present invention shown in FIG. 12 providing air apertures;

FIG. 16 is a diagram illustrating characteristics of the fan with fan frame of the invention and the conventional fan frame in a way of air pressure curves with respect to flow rate; and

FIG. 17 is a diagram illustrating characteristics of the fan with fan frame of the invention and the conventional fan frame in a way of noise curves with respect to fan speed.

### DETAILED DESCRIPTION OF THE INVENTION

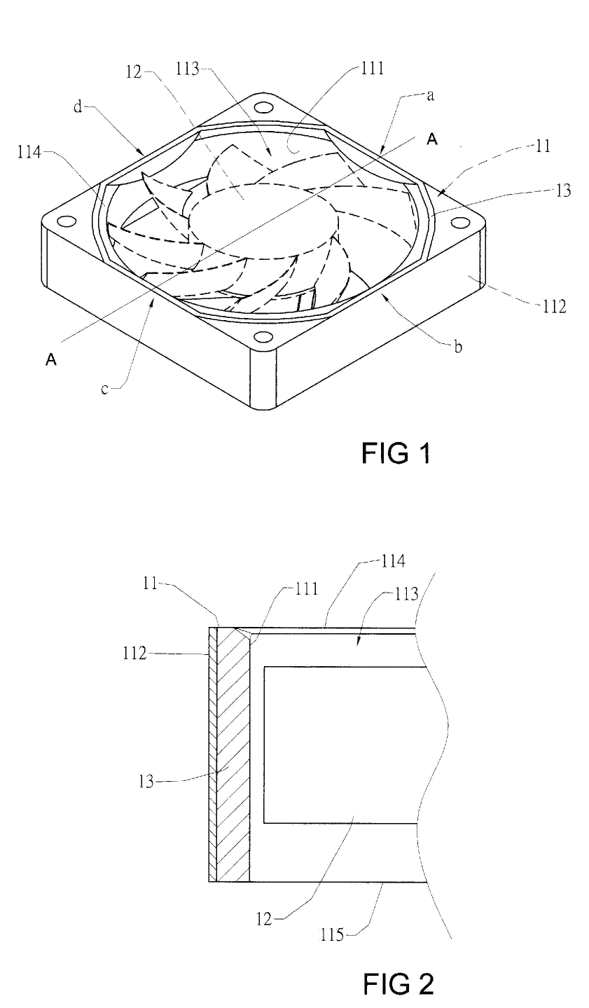

Referring to FIGS. 1 and 2, the first embodiment of a fan frame device according to the present invention provides a frame member 11, which has an inner frame side 111 and an outer frame side 112. The inner frame side 111 defines a flow path 113 for receiving a fan wheel 12. An inlet 114 and an outlet 115 of the flow path 113 are formed at the front side and the rear side of the frame member 11 respectively. The outer frame side 112 defines the size of the frame member 11. The frame member 11 is made of plastics and integrally joined to a metal reinforcing member 13 as a single piece by means of, for instance, the plastic frame member 11 being joined to the metal reinforcing member 13 preset in a molding tool during injection molding being performed.

The plastic frame member 11 provides a gross volume greater than the metal reinforcing member 13. Each of the four sides of the frame member 11 provides the shortest distance between the frame inner side 111 and the frame outer side 112, that is, spots a, b, c, d indicated by an arrow respectively are the shortest distances between the frame inner side 111 and the frame outer side 112 such that the inner side 111 expands radially to the most. That is, dimension of the outer side 112 is the same as the conventional fan frame but the inner side 11 provides a diameter greater than that of the conventional fan frame such that the spots a, b, c, and d are thinnest areas of the frame member 11.

The preceding metal reinforcing member 13 can be disposed next to the frame inner side 111 to face the fan wheel 12 as shown in FIG. 1 after the plastic frame 11 being joined to the metal reinforcing member 13. In other words, the inner side 111 is the metal reinforcing member 13.

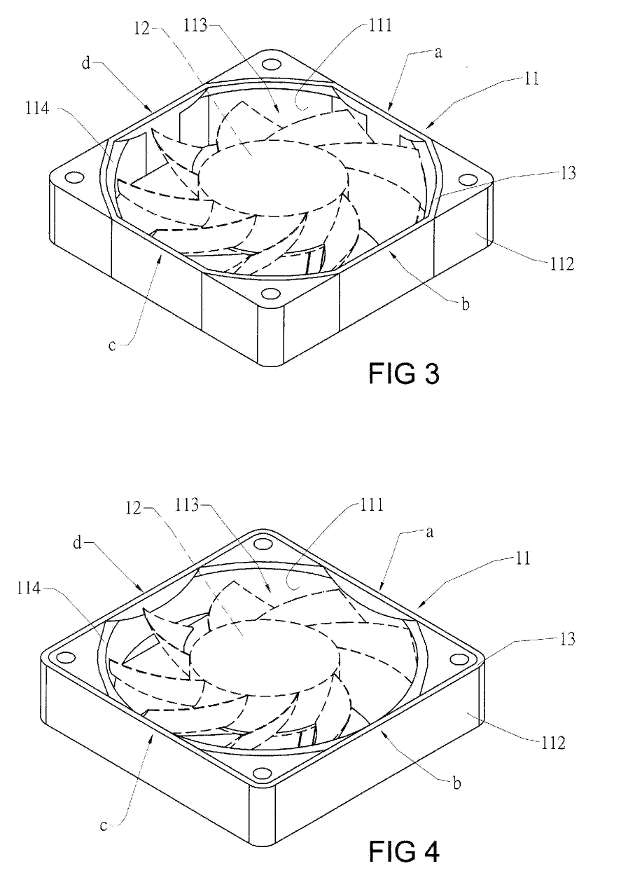

Referring to FIG. 3, the metal reinforcing member 13 can be disposed between the frame inner side 111 and the frame outer side 112 and exposes at the four thinnest areas a, b, c and d. That is, the thinnest areas a, b, c and d are formed by the metal reinforcing member 13. Referring to FIG. 4, the metal reinforcing member 13 can be disposed at the frame outer side 112, that is, the metal reinforcing member 13 constitutes the frame outer side 112.

The preceding metal reinforcing members 13 are belonged to annular type metal reinforced members 13. It is noted that discrete type metal reinforcing member 13 can be employed except the preceding annular type.

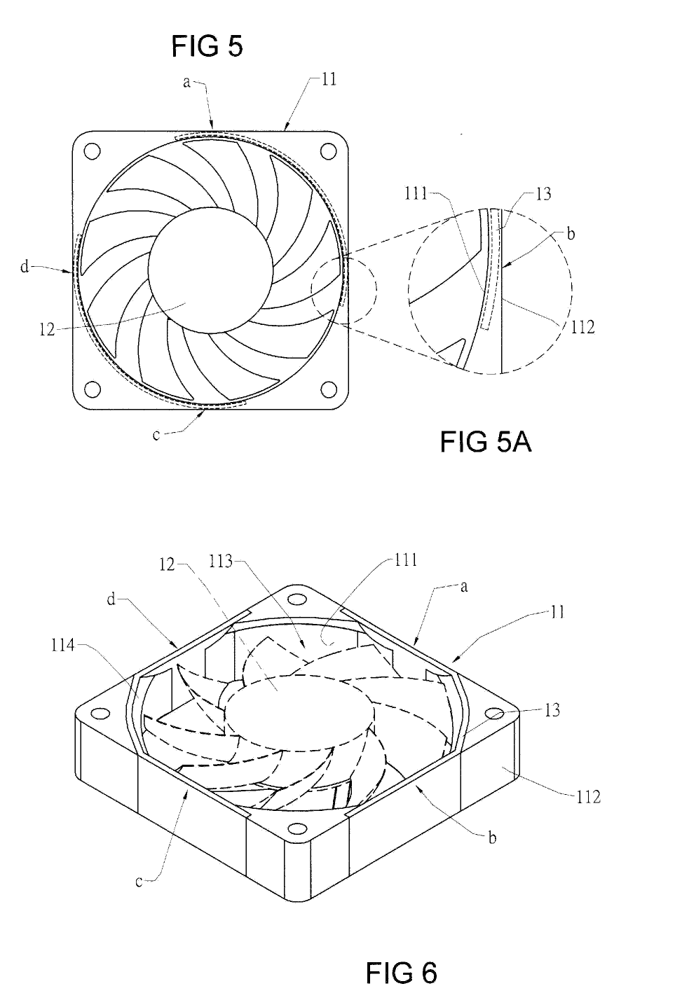

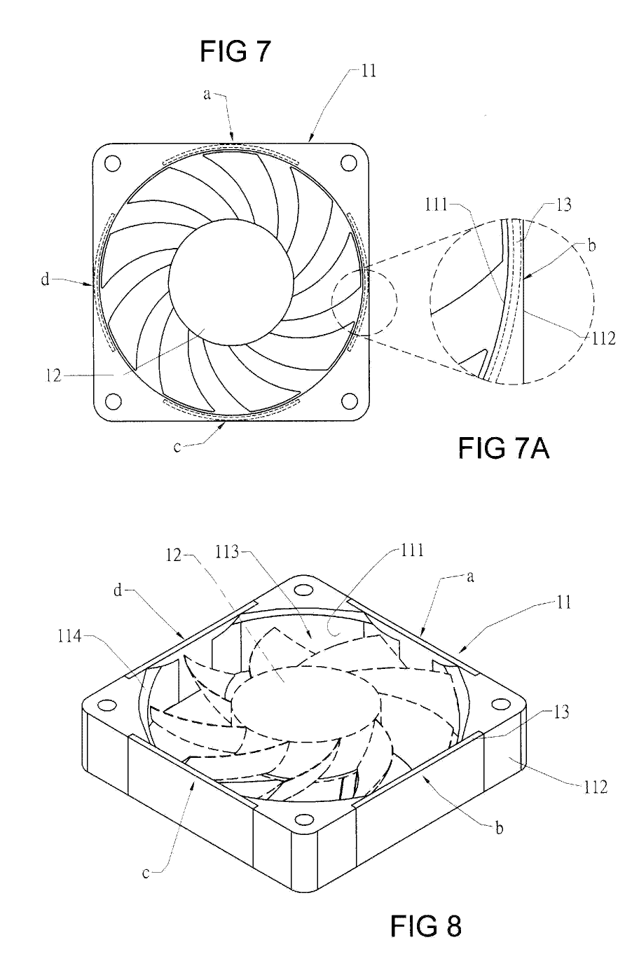

Referring to FIGS. 5 and 5A, the metal reinforcing member 13 is belonged to discrete type. The metal reinforcing member 13 is composed of a pair of metal reinforcing member parts and the two metal reinforced member parts are fixedly joined oppositely at the thinnest areas (a, b) and (c, d) respectively without exposure. Next, referring to FIG. 6, the metal reinforcing member parts are fixedly joined oppositely to the frame member 11 and expose at the thinnest areas (a, b) and (c, d) respectively. That is, the metal reinforcing member 13 constitute the thinnest areas a, b, c and d. Further, referring to FIGS. 7 and 7A, the metal reinforcing member 13 is composed of two pair of metal reinforcing member parts and the four metal reinforced member parts are fixedly joined at the four thinnest areas (a, b, c and d respectively without exposure. Further, referring to FIG. 8, the metal reinforcing member parts are fixedly joined to frame member 11 and expose at the thinnest areas (a, b) and (c, d) respectively. That is, the metal reinforcing member 13 constitute the thinnest areas a, b, c and d.

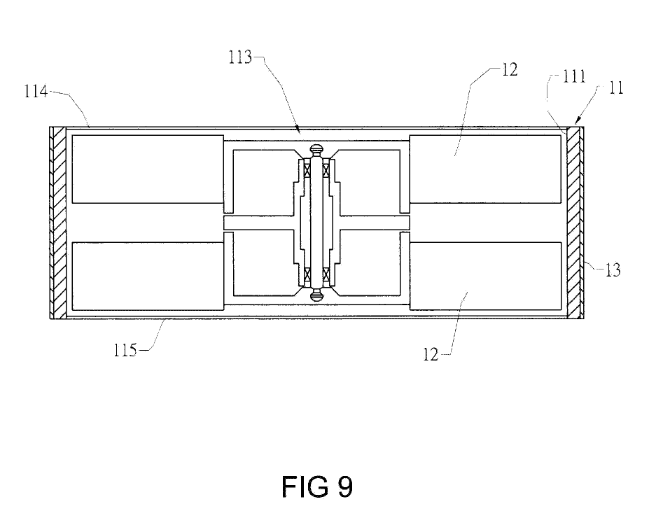

Referring to FIG. 9, two fan wheels 12 are capable of being arranged in series in the frame 11 instead of a single fan wheel 12 in the first embodiment. Of course, it is feasible that more than two fan wheels 12 in series are arranged in the frame member 11 in case of enough space being available in the frame 11.

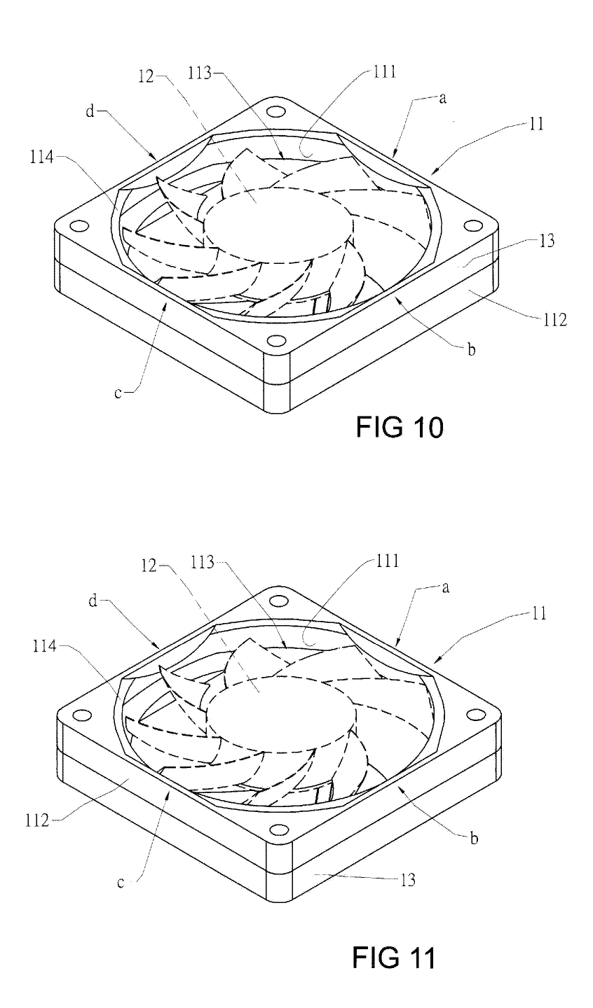

Referring to FIGS. 10 to 15, the second embodiment of a fan frame device according to the present invention is illustrated. The entire structure and functions of the second embodiment is almost the same as the preceding embodiment. The difference of the second embodiment from the preceding embodiment is in that the metal reinforcing member 13 provides a shape the same as the frame member 11 and is disposed next to the inlet 114 as shown in FIG. 10, next to the outlet 115 as shown in FIG. 11 or between the inlet 114 and the outlet 115 as shown in FIG. 13. It is noted that the frame member 11 is divided into two portions and the metal reinforcing member 13 is sandwiched by the two portions of the frame member 11.

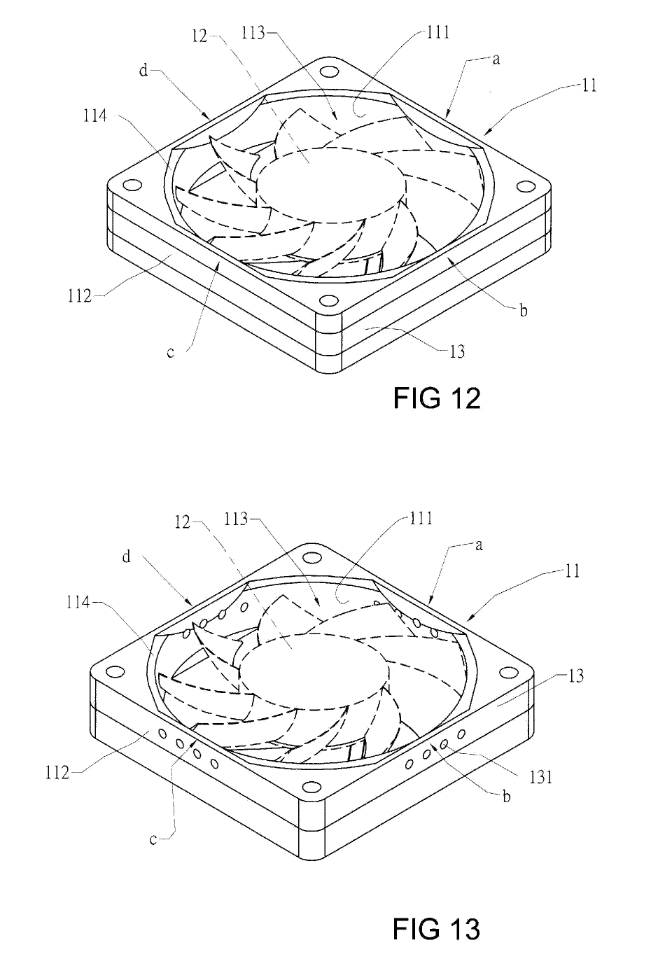

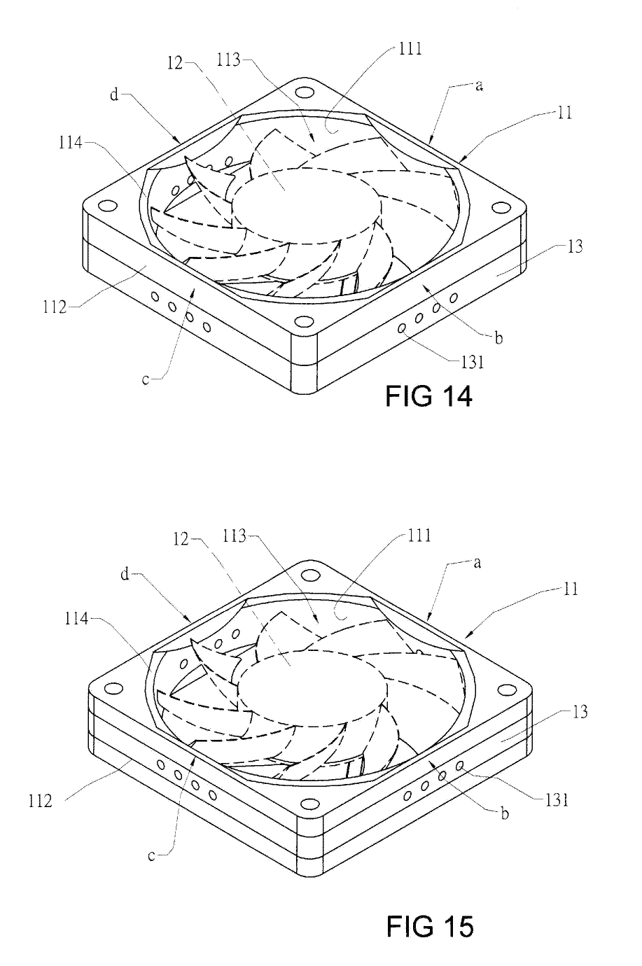

Referring to FIGS. 13 to 15, the metal reinforcing member 13 in FIG. 13 is almost the same as that shown in FIG. 10, the metal reinforcing member 13 in FIG. 14 is almost the same as that shown in FIG. 11 and the metal reinforcing member 13 shown in FIG. 15 is almost the same as that shown in FIG. 12. The difference of the metal reinforcing member 13 shown in FIGS. 11 to 13 respectively from that shown in FIGS. 10 to 12 is in that a plurality of apertures 131 are provided at the lateral sides of the metal reinforcing member 13 for admitting fluid and increasing air flow induced by the fan.

Furthermore, the metal reinforcing member 13 in the preceding embodiments can be made of high strengthen compound material such as polymeric fiber and/or carbon fiber and/or plastic fiber and/or carbon-plastic fiber instead of metal.

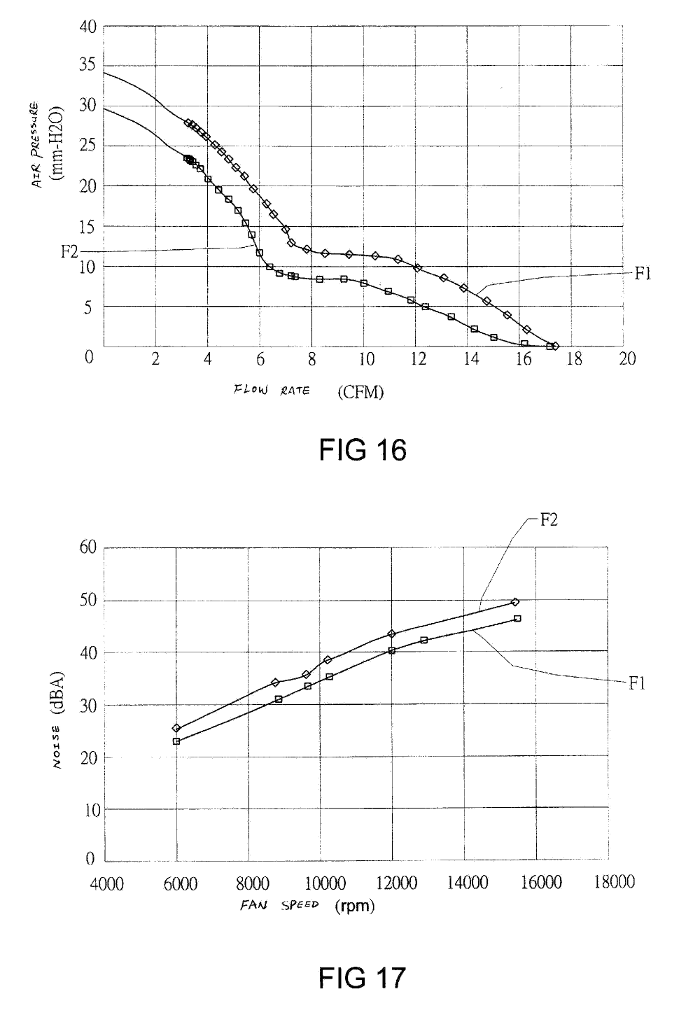

Referring to FIG. 16, curve of the air pressure in relation to flow rate is for the fan F1, which provides the fan frame of the present invention, and curve of the air pressure in relation to flow rate is for the fan F2, which provides the conventional fan frame. Due to the diameter of the inner side in the fan frame of the present invention is greater than that of the conventional fan frame and a bigger sized fan wheel is able to be mounted to the fan frame of the present invention, the air pressure induced by the fan F1 is greater than that induced by the fan with the conventional fan frame under a condition of the same flow rate and, by the same token, the air flow of the fan F1 is greater than that of the fan with the conventional fan frame under a condition of the same air pressure. Hence, entire fan characteristics of the fan F1 are much higher than those of the fan F2.

Referring to FIG. 17, curve of noise in relation to fan speed for the fan F1 provides the fan frame of the present invention and curve of noise in relation to fan speed for the fan F2 provides the conventional fan frame. Taking a range of fan speed between 6,000 rpm and 16,000 rpm for explanation, it can be seen the noise of the fan F1 is between 23 dBA and 45 dBA but the noise of the fan F2 is between 26 dBA and 49 dBA. That is, the fan F1 generates lower noise than the fan F2 because of the fan frame of the present invention is composed of a plastic frame and a metal member.

As the foregoing, it is appreciated that comparing to the prior art, the fan frame structure of the application has the following advantages:

1. The plastic frame member 11 is joined to the metal reinforcing member 13, which also can be made of compound material, intimately for lessening noise generated from the fluid impacting the frame member 11 and diminishing consonant vibrations during the fan wheel 12 running in addition to intensifying strength thereof.

2. The frame member 11 is integrally joined to the metal reinforcing member 13 or the compound member provides higher strength such that the inner side 111 of the frame member 11 can be arranged to expand radially and outwardly toward the outer sides 112 to the most to obtain the bigger diameter of the inner side 111 than the prior art. In this way, the inlet and outlet of the frame member 11 becomes larger and more flow rate and higher air pressure can be obtained. Further, the flow passage 113 surrounded by the inner side 111 becomes more space for accommodating larger fan wheel 12 and increasing the flow rate.

3. The thinnest spots a, b, c and d of the frame member 11 can be obtained once the inner side of the frame member 11 expands radially toward the outer sides 112 to the most under support of the metal frame 15. Hence, it is capable of overcoming the deficiency of the conventional plastic fan frame providing insufficient strength and being easily deformed after being subjected to heat for a long period of time.

4. Due to the volume of the plastic frame member 11 is more than that of the metal reinforcing member 13, the entire fan frame of the present invention is lighter than the conventional metal fan frame so that not only the cost of the fan frame can be lowered but also it is capable of overcoming the problems of noise and vibrations, which the conventional metal fan frame is unable to breakthrough.

While the invention has been described with referencing to preferred embodiments thereof, it is to be understood that modifications or variations may be easily made without departing from the spirit of this invention, which is defined by the appended claims.

What is claimed is:

1. A fan frame device, comprising:
a plastic frame member with an inner side and an outer side, the inner side defining a flow path with an inlet and an outlet being disposed at two ends thereof, the outer side defining the size thereof; and
a metal reinforcing member, being joined to the frame member;
wherein, the inner side is arranged to have a largest diameter so that the flow passage provides more space for accommodating a large sized fan wheel;
whereby, strength of the frame member is reinforced, vibration and noise are reduced during a fan wheel running and integral effect of heat dissipation is enhanced largely.

2. The fan frame structure as defined in claim 1, wherein the metal reinforcing member is disposed next to the inner side, the outer side or a position between the inner side and the outer side.

3. The fan frame device as defined in claim 1, wherein the metal reinforcing member is annular.

4. The fan frame device as defined in claim 1, wherein the metal reinforcing member is discrete.

5. The fan frame device as defined in claim 4, wherein the metal reinforcing member is at least composed of a pair of metal reinforcing member parts.

6. The fan frame device as defined in claim 1, wherein the reinforcing member provides a volume greater than the metal reinforcing member.

7. The fan frame structure as defined in claim 1, wherein at least a thinnest spot is provided at the frame member between the outer and inner sides.

8. The fan frame structure as defined in claim 8, wherein the reinforcing member is joined to the thinnest spot.

9. A fan frame device, comprising:
a plastic frame member with an inner side and an outer side, the inner side defining a flow path and the outer side defining the size thereof; and
a metal reinforcing member, providing a shape the same as the frame for being joined to the frame member;
wherein, the inner side is arranged to have a largest diameter so that the flow passage provides more space for accommodating a large sized fan wheel;
whereby, strength of the frame is reinforced, vibration and noise are reduced during a fan wheel running and integral effect of heat dissipation is enhanced largely.

10. The fan frame device as defined in claim 10, wherein the reinforced member is joined to the frame member in a way of being next to the inlet of the frame member.

11. The fan frame device as defined in claim 10, wherein the reinforced member is joined to the frame member in a way of being next to the outlet of the frame member.

12. The fan frame device as defined in claim 10, wherein the frame member is composed of two frame member parts and the reinforced member is sandwiched by the two frame member parts.

13. The fan frame device as defined in claim 10, wherein the reinforced member provides a plurality of air apertures at the lateral sides thereof.

14. The fan frame device as defined in claim 1, wherein the reinforcing member is made of compound material such as polymeric fiber, carbon fiber, plastic fiber or carbon-plastic fiber instead.

15. The fan frame device as defined in claim 10, wherein reinforcing member is made of compound material such as polymeric fiber, carbon fiber, plastic fiber or carbon-plastic fiber instead.
